(19) United States
(12) Patent Application Publication
(10) Pub. No.: US 2022/0261182 A1
(43) Pub. Date: Aug. 18, 2022

(54) SUPERBLOCK LINKAGE SYSTEMS AND METHOD FOR ASYMMETRIC DIE PACKAGES

(71) Applicant: SK hynix Inc., Gyeonggi-do (KR)

(72) Inventors: Vadim GALENCHIK, Minsk (BY); Igor NOVOGRAN, Minsk (BY)

(21) Appl. No.: 17/177,573

(22) Filed: Feb. 17, 2021

(51) Int. Cl. G06F 3/06

(52) U.S. Cl. CPC G06F 3/0659; G06F 3/0673; G06F 3/064; G06F 3/0604

(57) ABSTRACT

Superblock linkage systems and methods use asymmetric die packages. A controller of a memory system selects a set number of dies in a plurality of memory packages, the set number of dies being less than the total number of dies in the plurality of memory packages. The plurality of memory packages includes multiple memory packages and at least one memory package, each of the multiple memory packages having a first number of dies, the one memory package having a second number of dies. Further, the controller: generates a superblock including physical blocks with the same number or different numbers on the selected dies; repeats the selection and generation to generate multiple superblocks; and performs an operation on a superblock selected from among the multiple superblocks.

### BACKGROUND

### 1. Field

Embodiments of the present disclosure relate to a scheme for linking physical blocks into a superblock in a memory system.

### 2. Description of the Related Art

The computer environment paradigm has shifted to ubiquitous computing systems that can be used virtually anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices.

Memory systems using memory devices provide excellent stability, durability, high information access speed, and low power consumption, since they have no moving parts. Examples of memory systems having such advantages include universal serial bus (USB) memory devices, memory cards having various interfaces such as a universal flash storage (UFS), and solid state drives (SSDs). In order to improve performance of memory systems, physical blocks from different packages and dies may be linked into a superblock (SB). In this context, embodiments of the invention arise.

### SUMMARY

Various aspects of the present invention include superblock linkage systems and methods for asymmetric the packages.

In one aspect of the present of the invention, a memory system includes a plurality of memory packages and a controller configured to control the plurality of memory packages and including a superblock manager. Each package includes a plurality of dies, each die including a plurality of planes, each plane including a plurality of physical blocks. The plurality of memory packages includes multiple memory packages and at least one memory package, each of the multiple memory packages having a first number of dies, the one memory package having a second number of dies. The superblock manager is configured to: select a set number of dies in the plurality of memory packages, the set number of dies being less than the total number of dies in the plurality of memory packages; generate a superblock including physical blocks with the same number or different numbers on the selected dies; repeat the selection and generation to generate multiple superblocks; and perform an operation on a superblock selected from among the multiple superblocks.

In another aspect of the present invention, a method for operating a memory system including a plurality of memory packages includes selecting a set number of dies in the plurality of memory packages. The set number of dies is less than the total number of dies in the plurality of memory packages. Each package includes a plurality of dies, each die including a plurality of planes, each plane including a plurality of physical blocks. The plurality of memory packages includes multiple memory packages and at least one memory package, each of the multiple memory packages having a first number of dies, the one memory package having a second number of dies. Further, the method includes: generating a superblock including physical blocks with the same number or different numbers on the selected dies; repeating the selection and generation to generate multiple superblocks; and performing an operation on a superblock selected from among the multiple superblocks.

Additional aspects of the present invention will become apparent from the following description.

### BRIEF DESCRIPTION OF THE DRAWINGS

FIG. 1 is a block diagram illustrating a data processing system in accordance with an embodiment of the present invention.

FIG. 2 is a block diagram illustrating a memory system in accordance with an embodiment of the present invention.

FIG. 3 is a circuit diagram illustrating a memory block of a memory device in accordance with an embodiment of the present invention.

FIG. 4 is a diagram illustrating a memory system in accordance with an embodiment of the present invention.

FIG. 5 is a diagram illustrating an example of a structure of a memory package.

FIG. 6 is a diagram illustrating an example of a linkage of a super block.

FIG. 7 is a diagram illustrating a linkage of a super block in accordance with an embodiment of the present invention.

FIG. 8 is a diagram illustrating an example of a linkage of a super block in accordance with an embodiment of the present invention.

FIG. 9 is a flowchart illustrating an operation for managing a super block in accordance with an embodiment of the present invention.

### DETAILED DESCRIPTION

Various embodiments of the present invention are described below in more detail with reference to the accompanying drawings. The present invention may, however, be embodied in different forms and thus should not be construed as limited to the embodiments set forth herein. Rather, these embodiments are provided so that this disclosure is thorough and complete, and fully conveys the scope of the present invention to those skilled in the art. Moreover, reference herein to “an embodiment,” “another embodiment,” or the like is not necessarily to only one embodiment, and different references to any such phrase are not necessarily to the same embodiment(s). Throughout the disclosure, like reference numerals refer to like parts in the figures and embodiments of the present invention.

The invention can be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task, As used herein, the term ‘processor’ or the like refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The scope of the invention is limited only by the claims. The invention encompasses numerous alternatives, modifications and equivalents within the scope of the claims. Numerous specific details are set forth in the following description in order to provide a thorough understanding of the invention. These details are provided for the purpose of example; the invention may be practiced according to the claims without some or all of these specific details. For clarity, technical material that is known in technical fields related to the invention has not been described in detail so that the invention is not unnecessarily obscured.

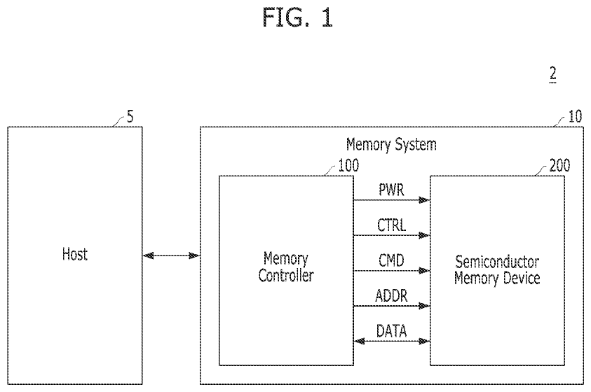

FIG. 1 is a block diagram illustrating a data processing system 2 in accordance with an embodiment of the present invention.

Referring FIG. 1, the data processing system 2 may include a host device 5 and a memory system 10. The memory system 10 may receive a request from the host device 5 and operate in response to the received request. For example, the memory system 10 may store data to be accessed by the host device 5.

The host device 5 may be implemented with any of various types of electronic devices. In various embodiments, the host device 5 may include an electronic device such as a desktop computer, a workstation, a three-dimensional (3D) television, a smart television, a digital audio recorder, a digital audio player, a digital picture recorder, a digital picture player, and/or a digital video recorder and a digital video player. In various embodiments, the host device 5 may include a portable electronic device such as a mobile phone, a smart phone, an e-book, an MP3 player, a portable multimedia player (PMP), and/or a portable game player.

The memory system 10 may be implemented with any of various types of storage devices such as a solid state drive (SSD) and a memory card. In various embodiments, the memory system 10 may be provided as one of various components in an electronic device such as a computer, an ultra-mobile personal computer (PC) (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, a radio-frequency identification (RFID) device, as well as one of various electronic devices of a home network, one of various electronic devices of a computer network, one of electronic devices of a telematics network, or one of various components of a computing system.

The memory system 10 may include a memory controller 100 and a semiconductor memory device 200. The memory controller 100 may control overall operation of the semiconductor memory device 200.

The semiconductor memory device 200 may perform one or more erase, program, and read operations under the control of the memory controller 100. The semiconductor memory device 200 may receive a command CMD, an address ADDR and data DATA through input/output lines. The semiconductor memory device 200 may receive power PWR through a power line and a control signal CTRL through a control line. The control signal CTRL may include a command latch enable signal, an address latch enable signal, a chip enable signal, a write enable signal, a read enable signal, as well as other operational signals depending on design and configuration of the memory system 10.

The memory controller 100 and the semiconductor memory device 200 may be integrated in a single semiconductor device such as a solid state drive (SSD). The SSD may include a storage device for storing data therein. When the semiconductor memory system 10 is used in an SSD, operation speed of a host device (e.g., host device 5 of FIG. 1) coupled to the memory system 10 may remarkably improve.

The memory controller 100 and the semiconductor memory device 200 may be integrated in a single semiconductor device such as a memory card. For example, the memory controller 100 and the semiconductor memory device 200 may be so integrated to configure a personal computer (PC) card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and/or a universal flash storage (UFS).

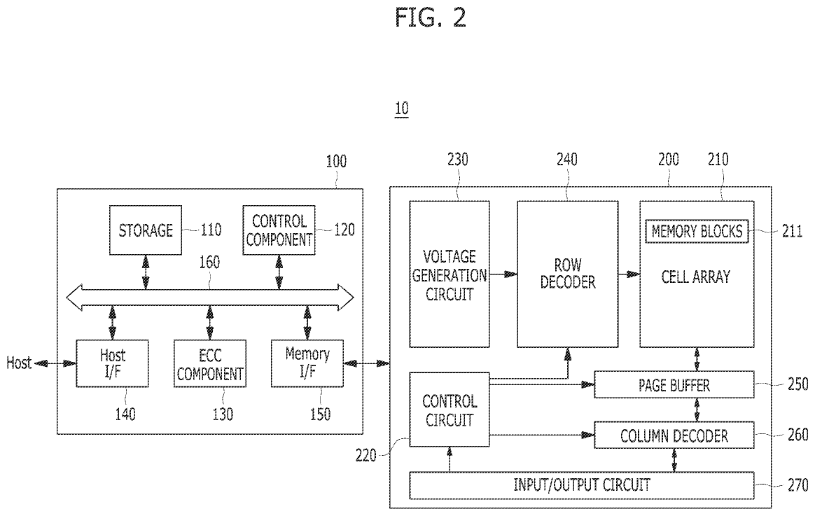

FIG. 2 is a block diagram illustrating a memory system in accordance with an embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device (e.g., host device 5 of FIG. 1), and in particular, store data to be accessed by the host device.

The memory device 200 may store data to be accessed by the host device.

The memory device 200 may be implemented with a volatile memory device such as a dynamic random access memory (DRAM) and/or a static random access memory (SRAM) or a non-volatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), and/or a resistive RAM (RRAM).

The controller 100 may control storage of data in the is memory device 200. For example, the controller 100 may control the memory device 200 in response to a request from the host device. The controller 100 may provide data read from the memory device 200 to the host device, and may store data provided from the host device into the memory device 200.

The controller 100 may include a storage 110, a control component 120, which may be implemented as a processor such as a central processing unit (CPU), an error correction code (ECC) component 130, a host interface (I/F) 140 and a memory interface (I/F) 150, which are coupled through a bus 160.

The storage 110 may serve as a working memory of the memory system 10 and the controller 100, and store data for driving the memory system 10 and the controller 100. When the controller 100 controls operations of the memory device 200, the storage 110 may store data used by the controller 100 and the memory device 200 for such operations as read, write, program and erase operations.

The storage 110 may be implemented with a volatile memory such as a static random access memory (SRAM) or a dynamic random access memory (DRAM), As described above, the storage 110 may store data used by the host device in the memory device 200 for the read and write operations. To store the data, the storage 110 may include a program memory, a data memory, a write buffer, a read buffer, a map buffer, and the like.

The control component 120 may control general operation of the memory system 10, and in particular a write operation and a read operation for the memory device 200 in response to a corresponding request from the host device. The control component 120 may drive firmware, which is referred to as a flash translation layer (FTL), to control general operations of the memory system 10. For example, the FTL may perform operations such as logical-to-physical (L2P) mapping, wear leveling, garbage collection, and/or bad block handling. The L2P mapping is known as logical block addressing (LBA).

The ECC component 130 may detect and correct errors in the data read from the memory device 200 during the read operation. The ECC component 130 may not correct error bits when the number of the error bits is greater than or equal to a threshold number of correctable error bits, but instead may output an error correction fail signal indicating failure in correcting the error bits.

In various embodiments, the ECC component 130 may perform an error correction operation based on a coded modulation such as a low density parity check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), or a Block coded modulation (BCM). However, error correction is not limited to these techniques. As such, the ECC component 130 may include any and all circuits, systems or devices for suitable error correction operation.

The host interface 140 may communicate with the host device through one or more of various interface protocols such as a universal serial bus (USB), a multi-media card (MMC), a peripheral component interconnect express (PCI-e or PCIe), a small computer system interface (SCSI), a serial-attached SCSI (SAS), a serial advanced technology attachment (SATA), a parallel advanced technology attachment (DATA), an enhanced small disk interface (ESDI), and/or an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the control component 120. When the memory device 200 is a flash memory such as a NAND flash memory, the memory interface 150 may generate control signals for the memory and process data under the control of the control component 120.

The memory device 200 may include a memory cell array 210, a control circuit 220, a voltage generation circuit 230, a row decoder 240, a page buffer 250 which may be in the form of an array of page buffers, a column decoder 260, and an input and output (input/output) circuit 270. The memory cell array 210 may include a plurality of memory blocks 211 which may store data. The voltage generation circuit 230, the row decoder 240, the page buffer array 250, the column decoder 260 and the input/output circuit 270 may form a peripheral circuit for the memory cell array 210. The peripheral circuit may perform a program, read, or erase operation on the memory cell array 210. The control circuit 220 may control the peripheral circuit.

The voltage generation circuit 230 may generate operation voltages of various levels. For example, in an erase operation, the voltage generation circuit 230 may generate operation voltages of various levels such as an erase voltage and a pass voltage.

The row decoder 240 may be in electrical communication with the voltage generation circuit 230, and the plurality of memory blocks 211. The row decoder 240 may select at least one memory block among the plurality of memory blocks 211 in response to a row address generated by the control circuit 220, and transmit operation voltages supplied from the voltage generation circuit 230 to the selected memory blocks.

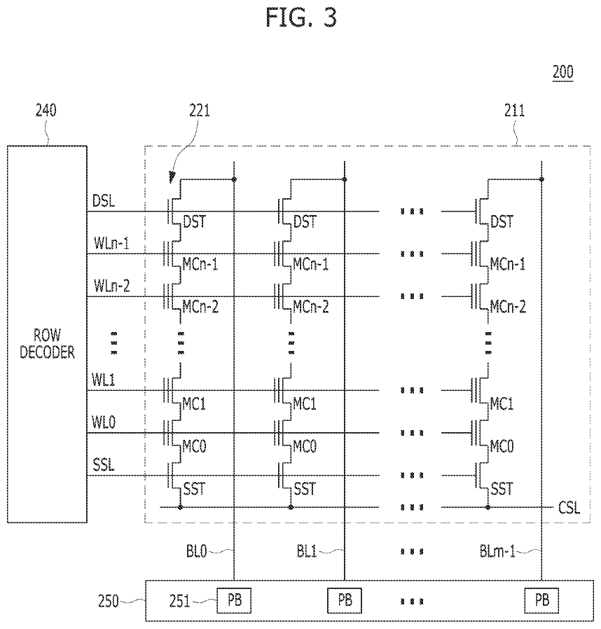

The page buffer 250 may be coupled with the memory cell array 210 through bit lines BL (shown in FIG. 3). The page buffer 250 may precharge the bit lines BL with a positive voltage, transmit data to, and receive data from, a selected memory block in program and read operations, or temporarily store transmitted data, in response to page buffer control signal(s) generated by the control circuit 220.

The column decoder 260 may transmit data to, and receive data from, the page buffer 250 or transmit and receive data to and from the input/output circuit 270.

The input/output circuit 270 may transmit to the control circuit 220 a command and an address, received from an external device (e.g., the memory controller 100 of FIG. 1), transmit data from the external device to the column decoder 260, or output data from the column decoder 260 to the external device, through the input/output circuit 270.

The control circuit 220 may control the peripheral circuit in response to the command and the address.

FIG. 3 is a circuit diagram illustrating a memory block of a semiconductor memory device in accordance with an embodiment of the present invention. For example, the memory block of FIG. 3 may be any of the memory blocks 211 of the memory cell array 210 shown in FIG. 2.

Referring to FIG. 3, the memory block 211 may include a plurality of word lines WL0 to WLn-1, a drain select line DSL and a source select line SSL coupled to the row decoder 240, These lines may be arranged in parallel, with the plurality of word lines between the DSL and SSL.

The memory block 211 may further include a plurality of cell strings 221 respectively coupled to bit lines BL0 to BLm−1. The cell string of each column may include one or more drain selection transistors DST and one or more source selection transistors SST. In the illustrated embodiment, each cell string has one DST and one SST. In a cell string, a plurality of memory cells or memory cell transistors MC0 to MCn−1 may be serially coupled between the selection transistors DST and SST. Each of the memory cells may be formed as a single level cell (SLC) storing 1 bit of data, a multi-level cell (MLC) storing 2 bits of data, a triple-level cell (TLC) storing 3 bits of data, or a quadruple-level cell (CLC) storing 4 bits of data.

The source of the SST in each cell string may be coupled to a common source line CSL, and the drain of each DST may be coupled to the corresponding bit line, Gates of the SSTs in the cell strings may be coupled to the SSL, and gates of the DSTs in the cell strings may be coupled to the DSL. Gates of the memory cells across the cell strings may be coupled to respective word lines. That is, the gates of memory cells MC0 are coupled to corresponding word line WL0, the gates of memory cells MC1 are coupled to corresponding word line WL1, etc. The group of memory cells coupled to a particular word line may be referred to as a physical page, Therefore, the number of physical pages in the memory block 211 may correspond to the number of word lines.

The page buffer array 250 may include a plurality of page buffers 251 that are coupled to the bit lines BL0 to BLm−1. The page buffers 251 may operate in response to page buffer control signals.

For example, the page buffers 251 may temporarily store data received through the bit lines BL0 to BLm−1 or sense voltages or currents of the bit lines during a read or verify operation.

In some embodiments, the memory blocks 211 may include NAND-type flash memory cells. However, the memory blocks 211 are not limited to such cell type, but may include NOR-type flash memory cells. Memory cell array 210 may be implemented as a hybrid flash memory in which two or more types of memory cells are combined, or one-NAND flash memory in which a controller is embedded inside a memory chip.

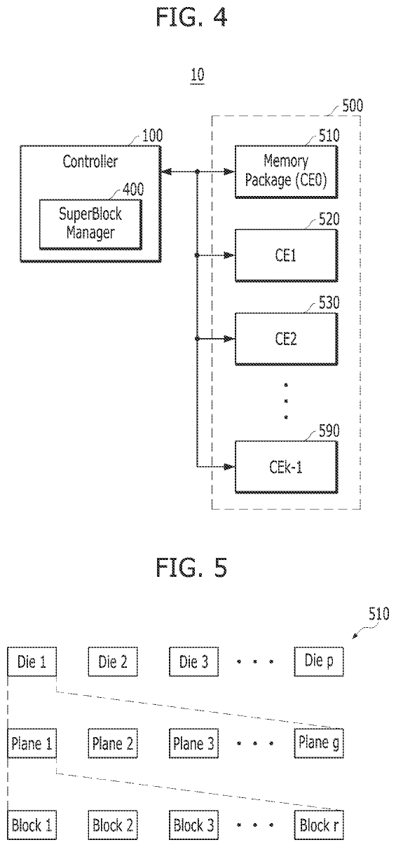

FIG. 4 is a diagram illustrating a memory system 10 in accordance with an embodiment of the present invention.

Referring to FIG. 4, the memory system 10 may include a controller 100 and a memory device 500. In some embodiments, the memory system 10 may be implemented with a solid state drive (SSD), based on NAND flash. The controller 100 may control the memory device 500 to perform various operations (e.g., read, write, and erase operations) for the memory device 500. Further, the controller 100 may control the memory device 500 to perform a background operation such as garbage collection and wear leveling. In some embodiments, the controller 100 may include a superblock manager 400. Details of the superblock manager 400 are described below.

The memory device 500 may include a plurality of memory packages, e.g., k memory packages including a zero-th memory package (CE0) 510 to a (k−1)-th memory package (CE(k−1)) 590. The memory device 500 may be coupled to the controller 10 through one or more channels (e.g., 2, 4 or 8 channels). In the illustrated example of FIG. 4, the memory packages may be coupled to the controller 100 through different channels. A memory package may be a small circuit board that contains memory chips. Non-limiting examples of a memory package may include Single In-line Memory Module (SIMM), Dual In-line Memory Module (DIMM), Small outline Dual In-Line Memory Module (SODIMM), and Rambus Inline Memory Module (RIMM).

FIG. 5 is a diagram illustrating an example of a structure of a memory package, e.g., the memory package (CE0) 510 of FIG. 4,

Referring to FIG. 5, the memory package (CE0) 510 may include a plurality of dies, e.g., p dies including a first die (Die 1) to a p-th die (Die p). Each die, e.g., the first die (Die 1) may include a plurality of planes, e.g., q planes including a first plane (Plane 1) to a q-th plane (Plane q). Each plane, e.g., the first plane (Plane 1) may include a plurality of blocks, e.g., r blocks including a first block (Block 1) to a r-th block (Block r).

In the memory system 10 such as NAND flash solid-state storage products, performance may be improved by linking physical blocks from different packages and dies into a super block (SB). Typically, SBs spread through all available dies to make the parallelism as effective as possible. The number of dies, i.e., physical blocks, is the power of 2 to simplify the flash translation layer (FTL) arithmetic. Therefore, the number of available SBs is limited by the number of blocks per die. It allows parallel operation with different physical blocks.

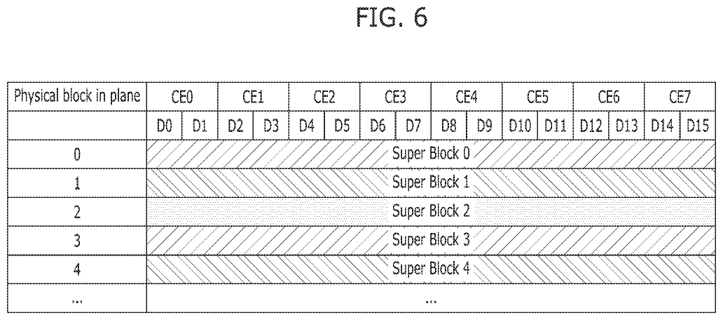

FIG. 6 is a diagram illustrating an example of a linkage of a super block.

Referring to FIG. 6, an example of SBs with eight packages (CE) and two dies (D#) per package is illustrated. To simplify further description herein and below, each die has only one plane. In the illustrated example, the amount of SBs is equal to the number of physical blocks per die, i.e., plane. For example, a zero-th super block includes zero-th physical blocks in 16 dies (i.e., planes) D0-D15. A first super block includes first physical blocks in 16 dies D0-D15. A second super block includes second physical blocks in 16 dies D0-D15. A third super block includes third physical blocks in 16 dies D0-D15. A fourth super block includes fourth physical blocks in 16 dies D0-D15. As such, for the typical SB linkage as shown in FIG. 6, physical blocks with the same number on all dies are linked to an SB.

When the number of free pages in a memory block is insufficient for write operations, free pages should be made by a set operation such as garbage collection (GC). Garbage collection is the process that makes a free region available by selecting programmed victim and free destination superblocks (SBs), moving the data of valid pages from the victim SB to the destination one, and erasing physical blocks from the victim SB. To satisfy quality of service (QoS) requirements, an algorithm for a GC trigger and throttling may be implemented in FTL. The main idea of the algorithm is splitting GC work into small portions to find a balance between the host and the GC write operation. The algorithm is based on several thresholds, e.g., a trigger threshold, an urgent threshold and throttling thresholds. A trigger threshold represents the number of free SBs to enable a GC procedure. An urgent threshold represents the number of free SBs to block host write commands processing for allocation of all required resources to a GC (i.e., an emergency procedure required to avoid running out of free space). Throttling thresholds for host and GC write operations ratio management may be defined by the number of free SBs. Used values of the mentioned thresholds significantly affect QoS characteristics. For example, earlier enabling a GC procedure by increasing trigger threshold leads to an increase of work for GC because of the higher validity of victim SB for GC. On the other hand, in the case of a later enabling GC procedure, the validity of a victim SB is lower but GC writes become a higher priority to avoid reaching the urgent threshold.

To increase QoS and performance characteristics of NAND flash products, it is necessary to make GC operations more effective. One of the ways to do this is to increase the number of the available SBs for more accurate and flexible tuning of the used thresholds for the GC trigger and throttling algorithm. A larger number of the available SBs allows finer tweaking of the ratio between the host and the background GC operations and making the background activity to have more spare time. However, it is expensive to increase overprovisioning by increasing the number of blocks per die. At the same time, the reduction of the die interleave has a negative effect on the sequential read/write performance. Accordingly, it is desirable to provide a scheme to increase the number of SBs using packages with different numbers of dies per package.

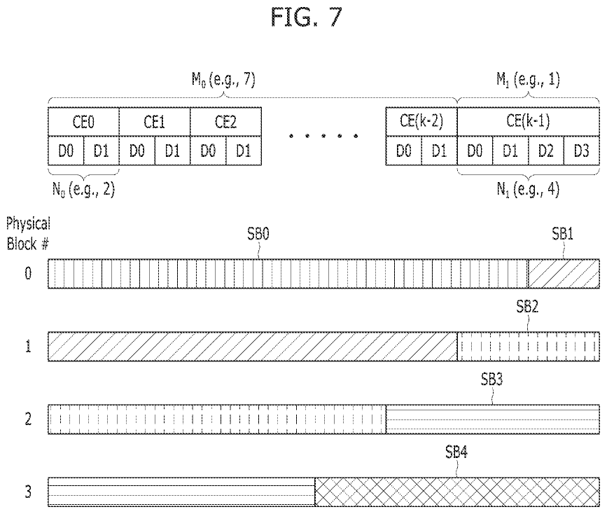

Various embodiments provide a scheme to use a structure of asymmetric packages, i.e., packages with different numbers of dies per package, and to link physical blocks into a superblock (SB) with die interleave equal to the power of 2. That is, an SB includes physical blocks with the same or different numbers on some dies of selected packages. Embodiments may provide a linkage of a super block, for example, a super block linkage as shown in FIG. 7. In FIG. 7, each die includes only one plane. However, a person of ordinary skill in the art would understand that embodiments may be easily extended to a multi-plane case, i.e., the case that each die includes multiple planes. The linkage scheme may be managed by the super block manager 400 of FIG. 4. For this linkage, parameters (or variables) may be defined as shown in List1:

List1:

N₀ and N₁: the number of dies per package for different packages,
where N₀ < N₁.
M₀ and M₁: the numbers of packages with N₀ and N₁ dies per
package, respectively. Both N₀ and N₁ are powers of 2. The total
number of packages (M₀ + M₁) is also the power of 2.

As defined in List1, N₀ and N₁ represent the number of dies per package for different packages, where N₀<N₁. M₀ and M₁ represent the numbers of packages with N₀ and N₁ dies per package, respectively. Both N₀ and N₁ are powers of 2. The total number of packages (M₀+M₁) is also the power of 2.

In some embodiments, the parameters above are: M₀=7, M₁=1, N₀=2 and N₁=4. In the illustrated example of FIG. 7, the total number of packages (M₀+M₁) is the power of 2 (i.e., 8) and N₀ and N₁ are powers of 2 (i.e., 6). Each of 7 packages CE0 to CE(k−1) (i.e., M₀=7) has a first number of dies (e.g., 2 dies, N₀=2), whereas 1 package CEk (i.e., M₁=1) has a second number of dies (e.g., 4 dies, N₁=4), Namely, at least one package CE(k−1) among a plurality of packages CE0 to CE(k−1) is asymmetric to the remaining packages CE0 to CE(k−2).

For the typical SB linkage as shown in FIG. 6, when physical blocks with the same number on all dies are linked to an SB, the die interleave should be (M₀ N₀+M₁ N₁). In this case, the number of available SB is N_{B}, where N_{B} is the number of physical blocks per plane.

According to embodiments, all physical blocks with the same number on all dies are not linked to an SB, as shown in FIG. 7. Instead, an SB is generated by linking physical blocks with die interleave equal to the power of 2. For example, an SB may include (M₀+M₁)N₀ physical blocks (e.g., (7+1)×2=16 physical blocks). The rest of the physical blocks with the same number may belong to the next SB. Therefore, a zeroth superblock SB0 may include physical blocks 0 (i.e., physical blocks with the number “0”) for dies from 0 to {(M₀+M₁)N₀ 1}. A first superblock SB1 may include physical blocks 0 for dies from (M₀+M₁)N₀ to {M₀N₀+M₁ N₁−1} and physical blocks 1 (i.e., physical blocks with the number “1”) for dies from 0 to {(M₀+M₁)N₀−(N₁−N₀)M₁−1}. A second superblock SB2 may include physical blocks 1 for dies from {(M₀+M₁)N₀−(N₁−N₀)M₁} to {M₀ N₀+M₁ N₁−1} and physical blocks 2 (i.e., physical blocks with the number “2”) for dies from 0 to {(M₀+M₁)N₀−2(N₁−N₀)M₁−1}. A third superblock SB 3 may include physical blocks 2 for dies from {(M₀+M₁)N₀−2(N₁−N₀)M₁} to {M₀ N₀+M₁ N₁−1} and physical blocks 3 (i.e., physical blocks with the number “3”) for dies from 0 to {(M₀+M₁)N₀−3(N₁−N₀)M₁−1}.

As can be seen from FIG. 7, embodiments provide more SBs in comparison with the scheme of FIG. 6. In accordance with embodiments, the total number of SB is determined by Equation

$${N}_{B} + ⌊ \frac{{N}_{B} ( {N}_{1} - {N}_{0} )}{( {M}_{0} + {M}_{1} ) {N}_{0}} ⌋ .$$

Since the scheme of FIG. 6 provides N_{B} SBs, embodiments provide additional

$$⌊ \frac{{N}_{B} ( {N}_{1} - {N}_{0} )}{( {M}_{0} + {M}_{1} ) {N}_{0}} ⌋$$

SBs available for operations (e.g., read, write, erase operations and a background operation such as garbage collection).

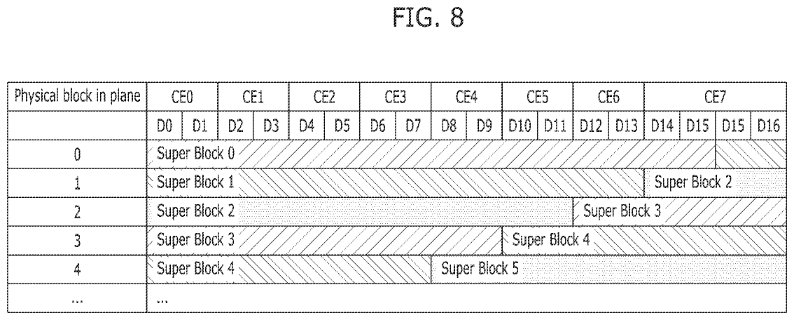

An example of a linkage scheme of a super block is described in below with reference to FIG. 8, A detailed description below is provided for an illustrative and descriptive purpose. It is not intended to limit the invention to a precise form. Modifications of parameters for the linkage scheme are possible to meet specific requirements.

In the illustrated example of FIG. 8, there are 7 packages CE0-CE7 and 18 dies D0-D17. In comparison with the typical case in FIG. 6, there are 4 dies per package in CE7. An SB includes physical blocks on 16 dies, For a hypothetical system where a die contains 1000 blocks per plane if all available 18 dies were linked to the SB in the typical way, the total number of available SBs would be 1000. For the same NAND, the suggested approach with a 16-die interleave gives the total number of SBs equal to 1125, which is determined by the Equation above

$${N}_{B} + ⌊ \frac{{N}_{B} ( {N}_{1} - {N}_{0} )}{( {M}_{0} + {M}_{1} ) {N}_{0}} ⌋ ,$$

A zero-th super block SB 0 includes physical blocks 0 for dies from [0, 15]. A first super block SB 1 includes physical blocks 0 for dies [16, 17], and physical blocks 1 for dies [0, 13], A second super block SB 2 includes physical blocks 1 for dies [14, 17] and physical blocks 2 for dies [0, 11]. A third super block SB 3 includes physical blocks 2 for dies from [12, 17], and physical blocks 3 for dies [0, 9]. A fourth super block SB 4 includes physical blocks 3 for dies [10, 17] and physical blocks 4 for dies [0, 7], A fifth super block SB 5 includes physical blocks 4 for dies from [8, 17], and physical blocks 5 for dies [0, 5].

As such, any SB includes physical blocks with different numbers. However, since these blocks are on different dies, operations such as read, write and erase operations may be done simultaneously, It is expected that FTL translation of the SB-based virtual address to the physical one gets more complicated. There is one more drawback.

If the packages use different channels, in some cases, data transfer parallelism might be broken. For example, it is considered that each package in FIG. 8 uses its one channel to transfer data. In this case, data transfer for dies D14-D17 is not simultaneous. It means that sequential data transfer for SB 0 is faster than for SB 2. However, since data transfer time is much less than programming or the read time, this drawback is not significant.

At the same level of overprovisioning, the SB linking approach in accordance with embodiments increases the number of available SB. At the same time, the read/write/erase operation parallelism is not broken and the cost of the memory system (e.g., SSD) does not increase dramatically, Additional SBs may be used for a more accurate GC trigger and throttling algorithm tuning, which should positively affect QoS of the memory system.

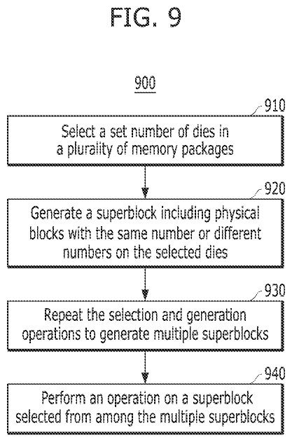

FIG. 9 is a flowchart illustrating an operation 900 for managing a super block in accordance with an embodiment of the present invention. The operation 900 may be managed by the super block manager 400 of the controller 100 in FIG. 4.

Referring to FIG. 9, at operation 910, the controller 100 may select a set number of dies in a plurality of memory packages, Each of the plurality of packages may include a plurality of dies. Each die may include a plurality of planes. Each plane may include a plurality of physical blocks. In some embodiments, the set number of dies is less than the total number of dies in the plurality of memory packages. For example, as shown in FIG. 8, the set number of dies is 16, which is less than the total number of dies (e.g., 18) in the plurality of memory packages, In some embodiments, the plurality of memory packages may include multiple memory packages and at least one memory package. Each of the multiple memory packages has a first number of dies, and the one memory package has a second number of dies.

At operation 920, the controller 100 may generate a superblock including physical blocks with the same number or different numbers on the selected dies. At operation 930, the controller 100 may repeat the selection and generation operations to generate multiple superblocks.

In some embodiments, the number of the plurality of memory packages is power of 2 (e.g., 8), and the one memory package is the last memory package (e.g., CE7) among the plurality of memory packages.

In some embodiments, the first number of dies is less than the second number of dies, and the first number of dies and the second number of dies are powers of 2. For example, the first number of dies is 2 and the second number of dies is 4.

In some embodiments, the multiple superblocks include a first superblock and a second superblock, which are adjacent to each other. The first superblock includes physical blocks with the same number on the selected dies. For example, the superblock 0 in FIG. 8 includes physical blocks with the same number (i.e., 0) on the selected dies D0-D15. The second superblock includes physical blocks with the different numbers on the selected dies. For example, the superblock 1 in FIG. 8 includes physical blocks with the number of 0 on dies D16-D17, and physical blocks with the number of 1 on dies D0-D13.

The multiple superblocks further include a third superblock adjacent to the second superblock. The third superblock includes physical blocks with the different numbers on the selected dies, For example, the superblock 2 in FIG. 8 includes physical blocks with the number of 1 on dies D14-D17, and physical blocks with the number of 2 on dies D0-D11.

At operation 940, the controller 100 may perform an operation on a superblock selected from among the multiple superblocks. In some embodiments, the operation includes at least one of read, write, erase and garbage collection operations.

As described above, embodiments provide a scheme to use a structure of asymmetric packages with different numbers of dies per package, and to link physical blocks into a superblock with die interleave equal to the power of 2. Embodiments improves the performance and QoS characteristics of a memory system (e.g., SSD product) by increasing the number of superblocks and the optimization of background operations, such as garbage collection (GC), without a significant increase in the device cost.

Although the foregoing embodiments have been illustrated and described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive. The present invention is intended to embrace all modifications and alternatives that fall within the scope of the claims.

What is claimed is:

1. A memory system comprising:
a plurality of memory packages, each package including a plurality of dies, each die including a plurality of planes, each plane including a plurality of physical blocks, the plurality of memory packages including multiple memory packages and at least one memory package, each of the multiple memory packages having a first number of dies, the one memory package having a second number of dies; and
a controller configured to control the plurality of memory packages and including a superblock manager configured to:
select a set number of dies in the plurality of memory packages, the set number of dies being less than the total number of dies in the plurality of memory packages;
generate a superblock including physical blocks with the same number or different numbers on the selected dies;
repeat the selection and generation to generate multiple superblocks; and
perform an operation on a superblock selected from among the multiple superblocks.

2. The memory system of claim 1, wherein the multiple superblocks include a first superblock including physical blocks with the same number on the selected dies, and a second superblock including physical blocks with the different numbers on the selected dies, the second superblock adjacent to the first superblock.

3. The memory system of claim 2, wherein the multiple superblocks further include a third superblock being adjacent to the second superblock, and including physical blocks with the different numbers on the selected dies.

4. The memory system of claim 1, wherein the one memory package is the last memory package among the plurality of memory packages.

5. The memory system of claim 1, wherein the first number of dies is less than the second number of dies.

6. The memory system of claim 1, wherein the first number of dies and the second number of dies are powers of 2.

7. The memory system of claim 1, wherein the number of the plurality of memory packages is a power of 2.

8. The memory system of claim 1, wherein the operation includes at least one of read, write, erase and garbage collection operations.

9. A method for operating a memory system including a plurality of memory packages, the method comprising:
selecting a set number of dies in the plurality of memory packages, the set number of dies being less than the total number of dies in the plurality of memory packages, each package including a plurality of dies, each die including a plurality of planes, each plane including a plurality of physical blocks, the plurality of memory packages including multiple memory packages and at least one memory package, each of the multiple memory packages having a first number of dies, the one memory package having a second number of dies;
generating a superblock including physical blocks with the same number or different numbers on the selected dies;
repeating the selection and generation to generate multiple superblocks; and
performing an operation on a superblock selected from among the multiple superblocks.

10. The method of claim 9, wherein the multiple superblocks include a first superblock including physical blocks with the same number on the selected dies, and a second superblock including physical blocks with the different numbers on the selected dies, the second superblock being adjacent to the first superblock.

11. The method of claim 10, wherein the multiple superblocks further include a third superblock being adjacent to the second superblock, and including physical blocks with the different numbers on the selected dies.

12. The method of claim 9, wherein the one memory package is the last memory package among the plurality of memory packages.

13. The method of claim 9, wherein the first number of dies is less than the second number of dies.

14. The method of claim 9, wherein the first number of dies and the second number of dies are powers of 2.

15. The method of claim 9, wherein the number of the plurality of memory packages is a power of 2.

16. The method of claim 9, wherein the operation includes at least one of read, write, erase and garbage collection operations.
